(19) United States
(12) Patent Application Publication
(10) Pub. No.: US 2014/0060874 A1
(43) Pub. Date: Mar. 6, 2014

(54) HOUSING OF ELECTRONIC DEVICE AND MANUFACTURING METHOD THEREOF

(71) Applicant: Quanta Computer Inc., Taoyuan Shien (TW)

(72) Inventor: Shu-Chen LIN, Taoyuan City (TW)

(73) Assignee: Quanta Computer Inc., Taoyuan Shien (TW)

(21) Appl. No.: 13/901,127

(22) Filed: May 23, 2013

(30) Foreign Application Priority Data
Aug. 31, 2012 (TW) 101131774

(51) Int. Cl. H05K 5/02

(52) U.S. Cl. CPC H05K 5/02
USPC 174/50; 156/309.6

(57) ABSTRACT

The present disclosure discloses a housing of an electronic device which includes a composite stack plate. The composite stack plate includes a resin layer and a plurality of fibered fabrics. The fibered fabrics are arranged at intervals, layered with each other and embedded in the resin layer. Each fibered fabric includes a plurality of fiber bundles. In the fibered fabrics, the fiber bundles of any two symmetrical layers have the same orientation. The present disclosure also discloses a manufacturing method thereof.

### RELATED APPLICATIONS

This application claims priority to Taiwan Patent Application Serial Number 101131774, filed Aug. 31, 2012, which is herein incorporated by reference.

### BACKGROUND

1. Technical Field

The present disclosure relates to a housing of an electronic device, and more particularly to a housing in which a fibered fabric having plural stacked layers being embedded in a resin layer.

2. Description of Related Art

In the marketplace, many portable electronic devices have been developed, and there are more functions provided and applicable for various purposes, wherein the mobile phone and notebook computer are the most favored portable electronic devices for being used for work or entertainment.

For enhancing the portability of a notebook computer, the thickness and the weight of the notebook computer are reduced, and the structural strength of the notebook computer is enhanced. However, the concepts of lessening the thickness and the weight of the notebook computer and increasing the structural strength of the notebook computer are conflict with each other.

So providing a novel design for the housing of the portable electronic device can compensate the conflict between the desire of reducing thickness and increasing sustainable strength. Skilled people in the art have been working on such design for the housing and consumers are also hoping to have such novel housing of the electronic device.

### SUMMARY

The present disclosure provides a housing of an electronic device and a manufacturing method thereof, in which the housing is made of a composite material for providing a thinner appearance and higher sustainable strength.

Because a composite material contains different materials and the deviation of material shrinkage rate, when the materials is cooled from the formation temperature to room temperature, a residual stress is generated in the materials, and a serious deformation may be occurred when the stacked direction is not symmetrical. Accordingly, the present disclosure discloses a housing of an electronic device and a manufacturing method thereof, wherein by controlling the distribution and orientation of the fiber bundles of each stacked fibered fabric (e.g., the included angle between material stacked directions and the number of stacked layers), a final product having proper combination of thickness and strength and low deformation rate can be obtained.

According to one embodiment of the present disclosure, the housing of the electronic device comprises a composite stack plate. The composite stack plate comprises a resin layer and plural fibered fabrics. The fibered fabrics are layered with each other, arranged at intervals, and embedded in the resin layer. Each fibered fabric comprises plural fiber bundles. Among these fibered fabrics, the fiber bundles of any two symmetrical layers of the fibered fabrics have the same orientation.

According to this embodiment, the manufacturing method of the housing of the electronic device comprises the steps of: a first fibered fabric and two resin films are provided; the two resin films are respectively laminated on two opposite sides of the first fibered fabric for forming a laminating structure; the laminating structure is heated for softening the two resin films of the laminating structure; the two softened resin films are respectively pressed, such that the two softened resin films are filled into gaps between fiber bundles of the fibered fabric for forming a fibered fabric layer; the fibered fabric layer is solidified; and a plurality of second fibered fabric are stacked and thermal pressed on the fibered fabric layer for forming a composite stack plate. Among these fibered fabrics, the patterns on the surfaces of the fibered fabrics arrange at two outmost opposite layers are the same, and the fiber bundles of the two fibered fabrics have the same orientation.

As what has been disclosed above, the present disclosure has advantages and improvements in comparison with prior art. With the provided technical solution, the present disclosure is novel and practical in used and widely applicable in various purposes, and at least has following advantages:

1. Providing features of thin in appearance while capable of sustaining high strength.

2. By controlling the distribution and orientation of the fiber bundles of the layered fibered fabrics, proper combination of thickness and strength and low deformation rate can be achieved, thereby preventing the fabric from being displaced which may cause problems of lowering the tensile strength and generating deformation.

### BRIEF DESCRIPTION OF THE DRAWINGS

The present disclosure will be apparent to those skilled in the art by reading the following detailed description of a preferred embodiment thereof, with reference to the attached drawings, in which:

FIG. 1A is a partial cross section view showing the composite stack plate of the housing of the electronic device according to an embodiment provided by present disclosure;

FIG. 1B is a partial cross section view showing the composite stack plate of the housing of the electronic device according to another embodiment provided by present disclosure;

FIG. 2A to FIG. 2M are exploded views in sequence showing the composite stack plate of the housing of the electronic device according to one alternative of the present disclosure;

FIG. 3 is a schematic view showing equipment adopted in the manufacturing method of the housing of the electronic device according to one embodiment of the present disclosure;

FIG. 4A is a schematic view showing the operation of the manufacturing method of the housing of the electronic device according to one alternative of this embodiment; and

FIG. 4B is a schematic view showing the operation of the manufacturing method of the housing of the electronic device according to another alternative of this embodiment.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

The inventor of the present disclosure finds out that because a composite material contains different materials and the deviation of material shrinkage, when the materials is cooled from the formation temperature to room temperature, a residual stress is generated in the materials, and a serious deformation may be occurred when the stacked direction is not symmetrical. In addition, the process of a fabric being impregnated in resin, due to that the fabric pattern formed on the surface of the fabric being disoriented and displaced, and the alignment of fiber direction being poor, often lead these fabrics being displaced, lowering the tensile strength and deformation problem. Thus, the housing of the electronic device provided by the present disclosure adopts the fibered fabrics having the same orientation being symmetrically layered together for forming a composite stack plate, and the composite stack plate can prevent from being seriously deformed, and further to prevent the tensile strength from being weakened.

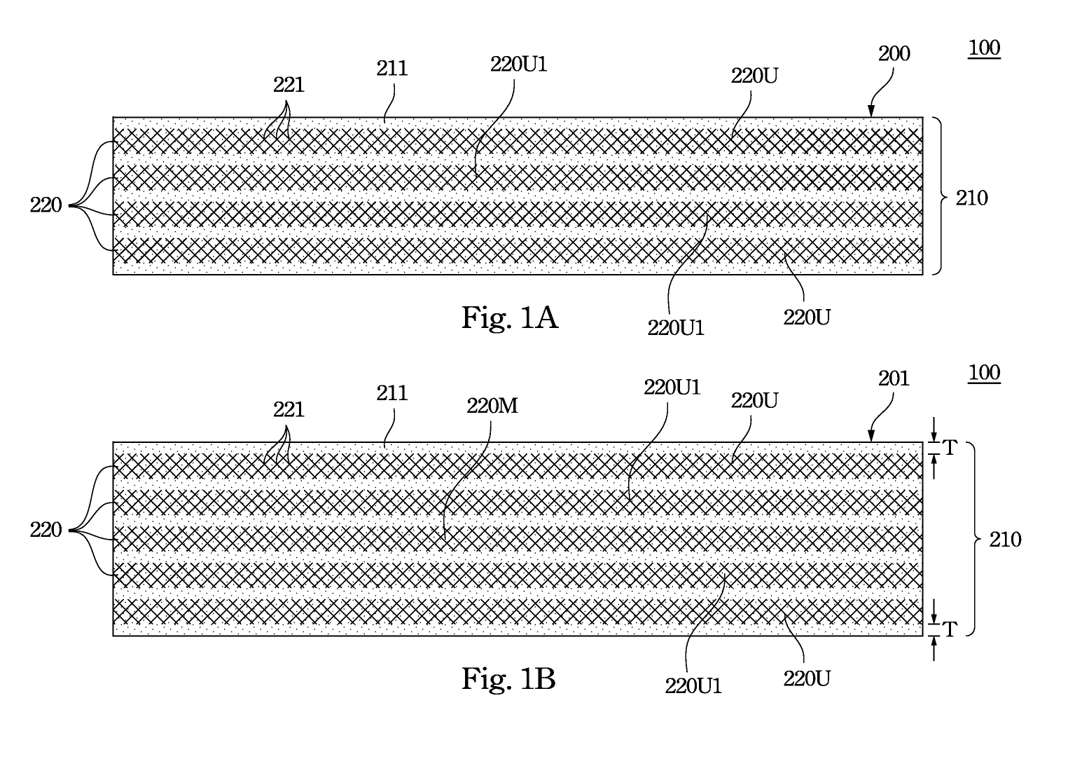

It is noted that, of the invention, if the number of fibered fabrics is even, the fibered fabrics are symmetrically arranged from the inner to the outer layers (e.g., four layers as shown in FIG. 1A); if the number of fibered fabrics is odd (e.g., five layers as shown in FIG. 1B), the outer oppositely fibered fabrics are symmetrically arranged relative to a median layer in the fibered fabrics.

FIG. 1A is a partial cross section view showing the composite stack plate 200 of the housing of the electronic device 100 according to an embodiment provided by present disclosure. The housing 100 is made of a composite stack plate 200. The composite stack plate 200 includes a resin layer 210 and four fibered fabrics 220 (a manufacturing method of the composite stack plate 200 will be illustrated later). The main material of which the resin layer 210 being made of is resin 211 or thermoplastic material, e.g., epoxy, phenol resin, thermoplastic resin such as PET, PC, PC/ABS, PMMA and PA. The fibered fabrics 220 are arranged at intervals, layered with each other and embedded in the resin layer 210; in other words, the fibered fabrics 220 are spaced from each other by the resin 211 of the resin layer 210. In addition, each fibred fabric 220 includes plural fiber bundles 221, e.g., plural fiber bundles 221 being longitudinally or transversally woven or plural fiber bundles 221 being unidirectionally arranged for having different orientations. The resin 211 of the resin layer 210 is filled into gaps between the fiber bundles 221 of each fibered fabric 220.

According to this embodiment, fibered fabrics 220U arranged at two outmost opposite layers have the same orientation or pattern, fibered fabrics 220U1 defined at two layers next to the outmost opposite layers also have the same orientation, so that the composite stack plate 200 can prevent from being seriously deformed and to further prevent the tensile strength from being weakened.

FIG. 1B is a partial cross section view showing the composite stack plate 201 of the housing of the electronic device 100 according to another embodiment provided by present disclosure. The difference from FIG. 1A is that the number of the fibred fabric 220 is five (odd number), which includes a fibered fabric 220M, two fibered fabrics 220U and two fibered fabrics 220U1. The fibered fabric 220M is arranged as a median layer (the third fibered fabric) thereof, the two fibered fabrics 220U is arranged at the outmost layers at two opposite sides of the fibered fabric 220M, and have the fiber bundles 221 with the same orientation (e.g., unidirectional fibered fabric having 0° or 90° orientation). The two fibered fabrics 220U1 is arranged next to the outmost layers at two opposite sides of the fibered fabric 220M, and have the fiber bundles 221 with the same orientation (e.g., unidirectional fibered fabric having 0 or 90° orientation).

It is noted that a designer can adopt the same or different or mixed types of fibered fabrics according to actual needs, e.g., in the composite stack plate 200, all the fibered fabrics 220 are carbon fibered fabrics, glass fibered fabrics or Kevlar fibered fabrics; or in a composite stack plate 201, the fibered fabrics 220 are a mixture of carbon fibered fabrics and glass fibered fabrics, or a mixture of carbon fibered fabrics and Kevlar fibered fabrics, or a mixture of glass fibered fabrics and Kevlar fibered fabrics. In addition, the designer can adopt the fibered fabric made by the same or different weaving method or the same or different weaving pattern, e.g., in the composite stack plate 201, the fibered fabrics 220 can be the same or can respectively be weaving canvas, knitting fibered fabrics, satin weaving fibered fabrics or specially-woven fabrics, according to the actual needs. Otherwise, the designer can adopt the fibered fabric in which each fiber bundle 221 has the same or different amount of fibers, according to the actual needs, e.g., in the composite stack plate 201, the amount of fibers in each fiber bundle 221 of the fibered fabrics 220 can be the same or can respectively be 1,000 pieces (1K), 3,000 pieces (3K), 6,000 pieces (6K) or 12,000 pieces (12K), according to the actual needs. Moreover, the designer can adopt the fibered fabric with the fiber bundles 221 having the same or different orientation, e.g., in the composite stack plate 201, the fiber bundles 221 of the fibered fabrics 220 can have the same or can respectively have unidirectional fibered fabric having 0°, 45°, 90° or 135° orientation.

According one embodiment of the present disclosure, the symmetrical fibered fabrics 220 also have the same types of fibered fabrics (e.g., the same carbon fibered fabrics, the glass fibered fabrics or the Kevlar fibered fabrics), the fibered fabric can be made by the same weaving method (e.g., the same weaving canvas, knitting fibered fabrics, satin weaving fibered fabrics) and the fibered fabrics can have the same amount of fibers.

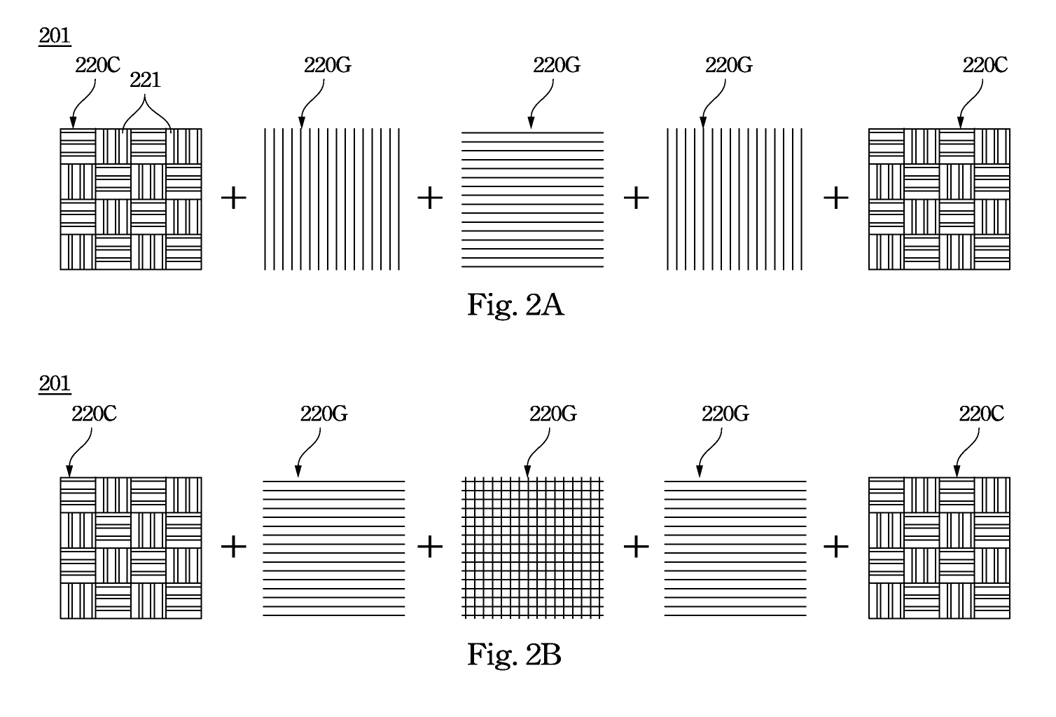

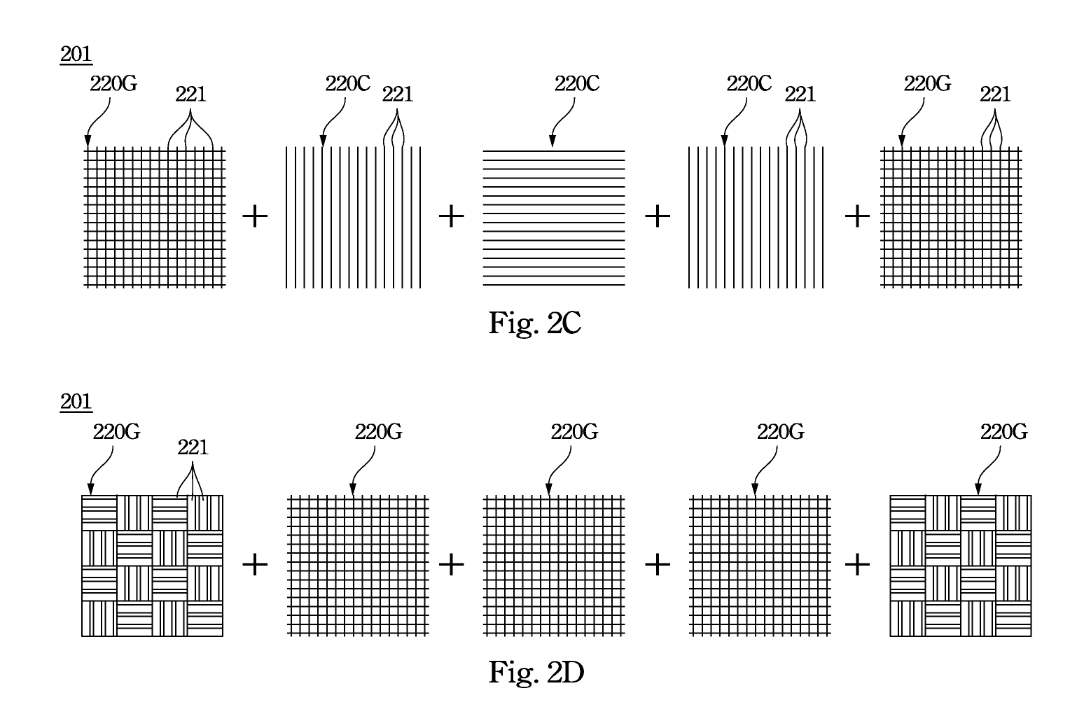

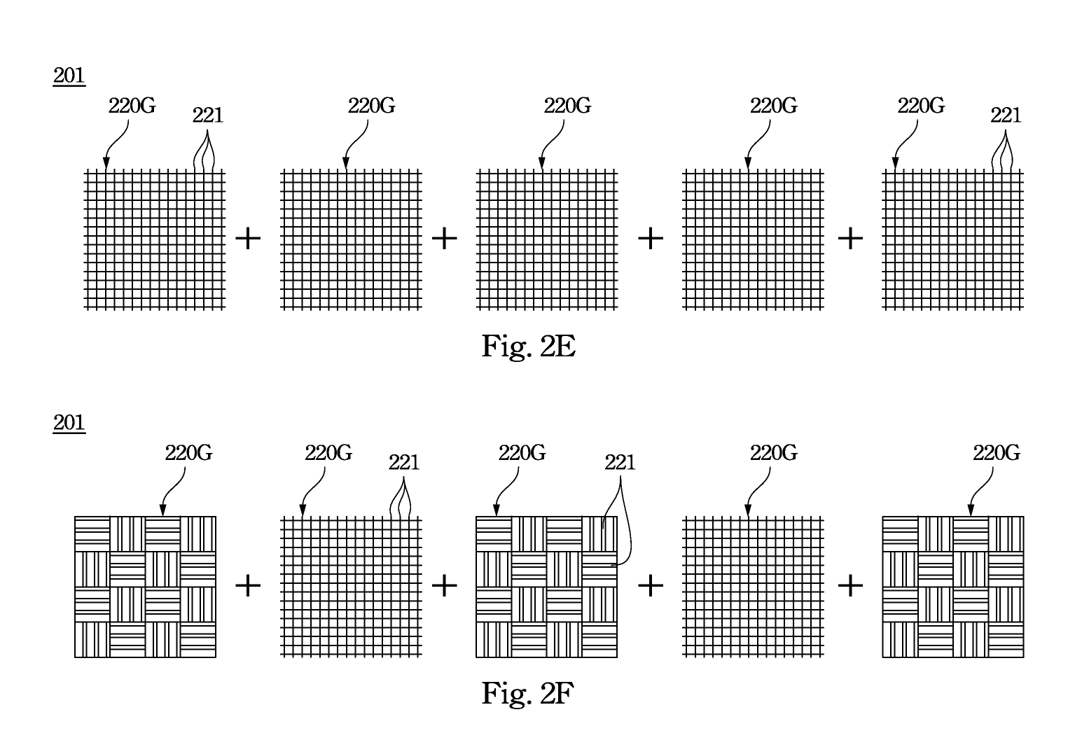

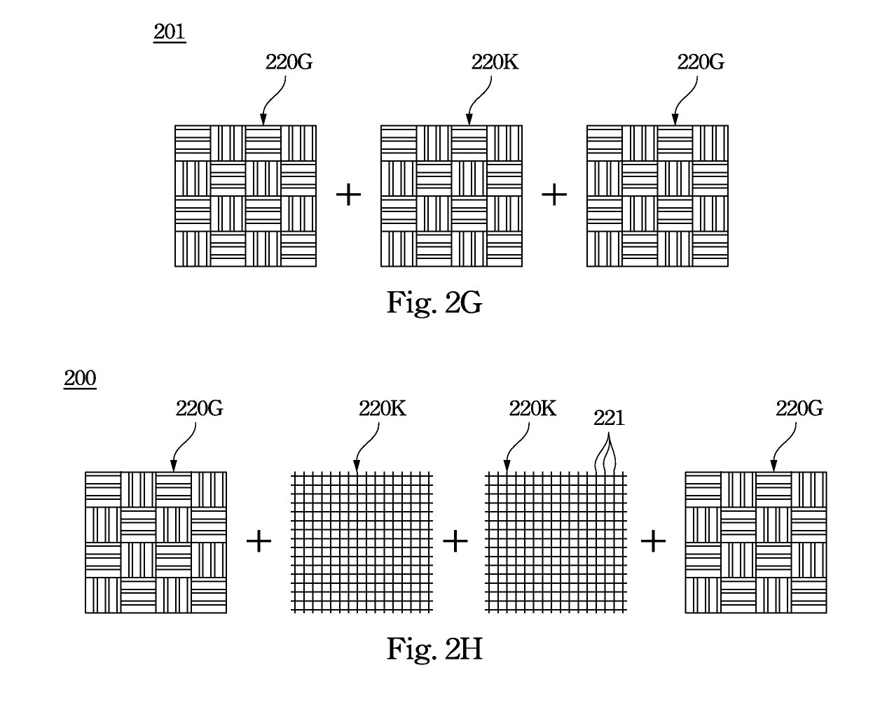

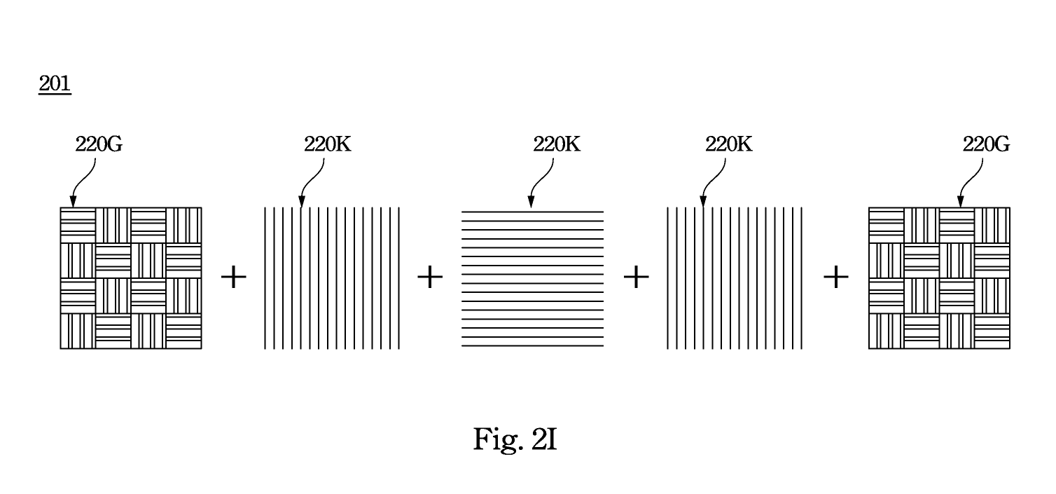

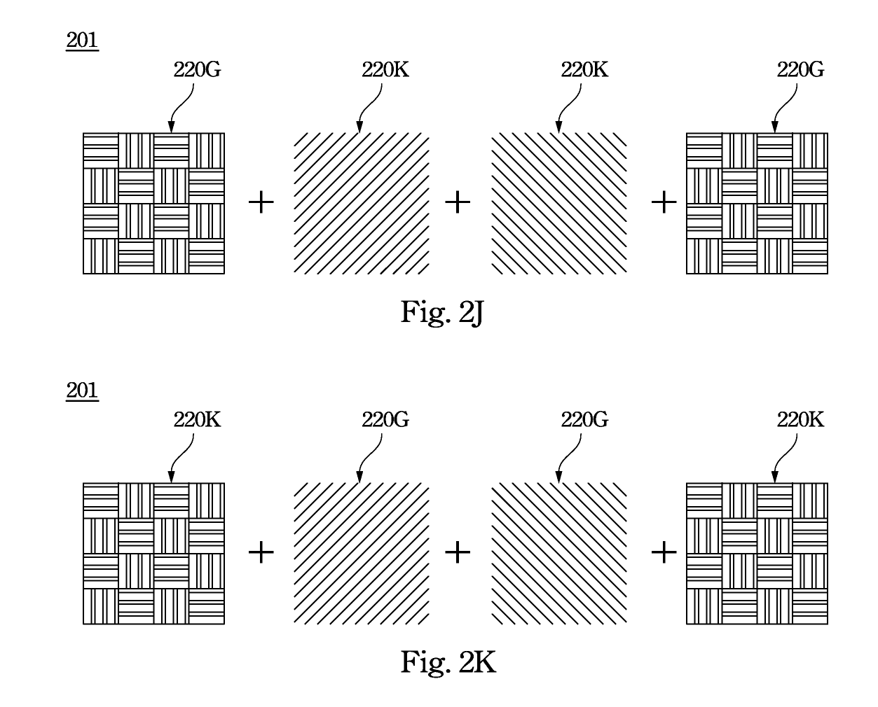

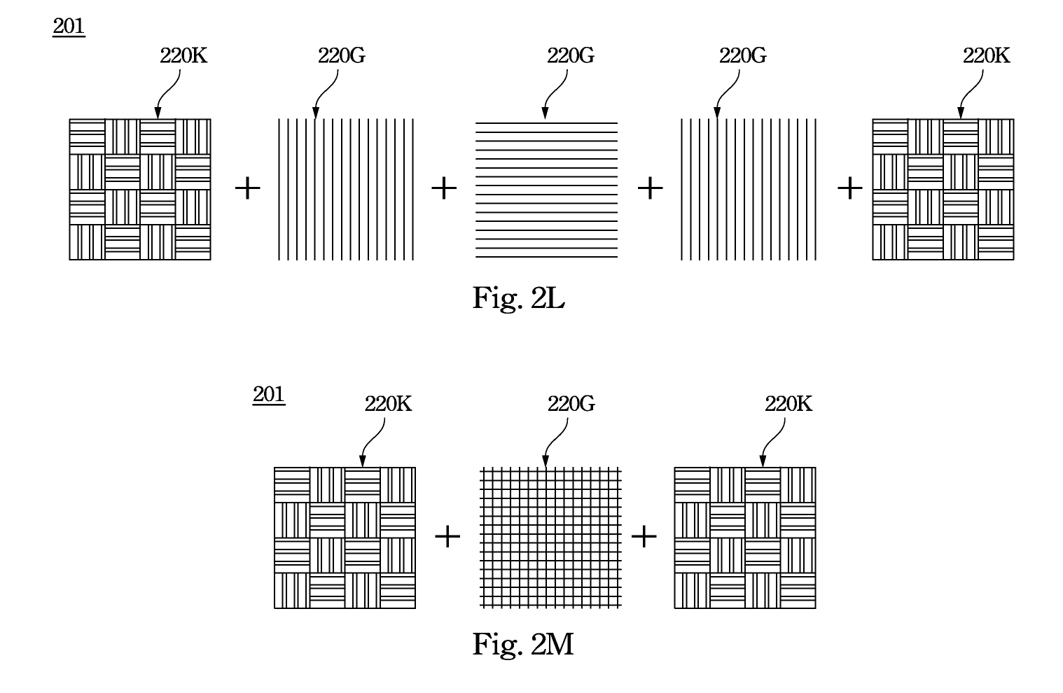

Reference is now made to FIG. 2A to FIG. 2M. FIG. 2A to FIG. 2M are exploded views in sequence showing the composite stack plate 200, 201 of the housing of the electronic device according to one alternative of the present disclosure.

As shown in FIG. 2A, take the five fibered fabrics 220 shown in FIG. 1B for example, in FIG. 2A, the fibered fabrics 220 of the composite stack plate 201 are respectively a carbon fibered fabric 220C having 3K fibers, a unidirectional glass fibered fabric 220G having 0° orientation, a unidirectional glass fibered fabric 220G having 90° orientation, a unidirectional glass fibered fabric 220G having 0° orientation and a carbon fibered fabric 220C having 3K fibers; and the thickness of the composite stack plate 201 is e.g., 0.6 mm˜1.0 mm. The fibered fabric 220M arranged in the median layer is the unidirectional glass fibered fabric 220G having 90° orientation, the carbon fibered fabrics 220C having 3K fibers at the outmost layers defined at two opposite sides thereof and the unidirectional glass fibered fabrics 220G having 0° orientation next to the outmost layers not only have the same type of fibered fabrics, also have the fiber bundles 221 with the same orientation. According to one embodiment, the fibered fabric 220G arranged at the third layer (i.e., the fibered fabric arranged in the median layer) can be optionally changed to a unidirectional glass fibered fabric having 0° orientation, the fibered fabrics 220G arranged at the second and the fourth layers can be optionally changed to a unidirectional glass fibered fabric having 90° orientation, as long as the symmetrical fiber bundles 221 at two opposite sides of the fibered fabric arranged in the median layer have the same orientation and the same type.

As shown in FIG. 2B, in the composite stack plate 201, the fibered fabrics 220 are respectively a carbon fibered fabric 220C having 3K fibers, a unidirectional glass fibered fabric 220G having 90° orientation, a glass fibered weaving canvas 220G, a unidirectional glass fibered fabric 220G having 90° orientation and a carbon fibered fabric 220C having 3K fibers; and the thickness of the composite stack plate 201 is e.g., 0.8 mm˜1.2 mm. The fibered fabric 220M arranged in the median layer is the glass fibered weaving canvas 220G, the carbon fibered fabrics 220C having 3K fibers at the outmost layers defined at two opposite sides thereof and the unidirectional glass fibered fabrics 220G having 90° orientation next to the outmost layers not only have the same type of fibered fabrics, also have the fiber bundles 221 with the same orientation. According to one embodiment, the fibered fabrics 220G arranged at the second and the fourth layers can be optionally changed to a unidirectional glass fibered fabric having 0° orientation.

As shown in FIG. 2C, in the composite stack plate 201, the fibered fabrics 220 are respectively a glass fibered weaving canvas 220G, a unidirectional carbon fibered fabric 220C having 90° orientation, a unidirectional carbon fibered fabric 220C having 0° orientation, a unidirectional carbon fibered fabric 220C having 90° orientation and a glass fibered weaving canvas 220G; and the thickness of the composite stack plate 201 is e.g., 0.6 mm˜1.0 mm. Wherein the fibered fabric 220M arranged in the median layer is the unidirectional carbon fibered fabric 220C having 0° orientation, the glass fibered weaving canvas 220G at the outmost layers defined at two opposite sides thereof and the unidirectional carbon fibered fabric 220C having 90° orientation next to the outmost layers not only have the same type of fibered fabrics, also have the fiber bundles 221 with the same orientation. According to one preferred embodiment, the fibered fabrics 220C arranged at the second and the fourth layers can be optionally changed to a unidirectional carbon fibered fabric 220C having 0° orientation; the fibered fabrics 220G arranged at the first and the fifth layers can be optionally changed to a unidirectional carbon fibered fabric 220C having 0° orientation.

As shown in FIG. 2D, in the composite stack plate 201, the fibered fabrics 220 are two glass fibered fabrics 220G having 3K fibers and three glass fibered weaving canvas 220G, the glass fibered weaving canvas 220G are disposed between the two glass fibered fabrics 220G having 3K fibers; and the thickness of the composite stack plate 201 is e.g., 0.8 mm˜1.5 mm. The fibered fabric 220M arranged in the median layer is the glass fibered weaving canvas 220G, the glass fibered fabrics 220G having 3K fibers at the outmost layers defined at two opposite sides thereof and the two glass fibered weaving canvas 220G next to the outmost layers not only have the same type of fibered fabrics, also have the fiber bundles 221 with the same orientation.

As shown in FIG. 2E, in the composite stack plate 201, the fibered fabrics 220 are five glass fibered weaving canvas 220G; and the thickness of the composite stack plate 201 is e.g., 0.8 mm˜1.5 mm. Wherein the fibered fabric 220M arranged in the median layer is the glass fibered weaving canvas 220G arranged at the third layer, the rest glass fibered weaving canvas 220G not only have the same type of fibered fabrics, also have the fiber bundles 221 with the same orientation.

As shown in FIG. 2F, in the composite stack plate 201, the fibered fabrics 220 are three glass fibered fabrics 220G having 3K fibers and two glass fibered weaving canvas 220G, each glass fibered weaving canvas 220G is disposed between any two glass fibered fabrics 220G having 3K fibers; and the thickness of the composite stack plate 201 is e.g., 0.8 mm˜1.5 mm. The fibered fabric 220M arranged in the median layer is the glass fibered fabrics 220G having 3K fibers, the glass fibered fabrics 220G having 3K fibers at the outmost layers defined at two opposite sides thereof and the glass fibered weaving canvas 220G next to the outmost layers not only have the same type of fibered fabrics, also have the fiber bundles 221 with the same orientation.

As shown in FIG. 2G, take three fibered fabrics for example, in FIG. 2G, the fibered fabrics 220 are respectively a glass fibered fabric 220G having 3K fibers, a Kevlar fibered fabric 220K having 3K fibers and a glass fibered fabric 220G having 3K fibers; and the thickness of the composite stack plate 201 is e.g., 0.8 mm˜1.5 mm. The fibered fabric 220M arranged in the median layer is the Kevlar fibered fabric 220K having 3K fibers, the glass fibered fabrics 220G having 3K fibers at two opposite sides thereof not only have the same type of fibered fabrics, also have the fiber bundles 221 with the same orientation.

As shown in FIG. 2H, take the four fibered fabrics 220 shown in FIG. 1A for example, in the composite stack plate 200, the fibered fabrics 220 are respectively a glass fibered fabric 220G having 3K fibers, a Kevlar fibered weaving canvas 220K, a Kevlar fibered weaving canvas 220K and a glass fibered fabric 220G having 3K fibers; and the thickness of the composite stack plate 200 is e.g., 0.8 mm˜1.2 mm. The fibered fabrics 220U arranged at the outmost layers at two opposite sides are the glass fibered fabrics 220G having 3K fibers which not only have the same type of fibered fabrics, also have the fiber bundles 221 with the same orientation. The two fibered fabrics 220U1 arranged at two layers next to the outmost opposite layers (inner layers) are the Kevlar fibered weaving canvas 220K which not only have the same type of fibered fabrics, also have the fiber bundles 221 with the same orientation

As shown in FIG. 2I, take the five fibered fabrics 220 shown in FIG. 1B for example, in the composite stack plate 201, the fibered fabrics 220 are respectively a glass fibered fabric 220G having 3K fibers, a unidirectional Kevlar fibered fabric 220K having 0° orientation, a unidirectional Kevlar fibered fabric 220K having 90° orientation, a unidirectional Kevlar fibered fabric 220K having 0° orientation and a glass fibered fabric 220G having 3K fibers; and the thickness of the composite stack plate 201 is e.g., 0.6 mm˜1.2 mm. The fibered fabric 220M arranged in the median layer is the unidirectional Kevlar fibered fabric 220K having 90° orientation, the glass fibered fabrics 220G having 3K fibers at the outmost layers defined at two opposite sides thereof and the unidirectional Kevlar fibered fabrics 220K having 0° orientation next to the outmost layers not only have the same type of fibered fabrics, also have the fiber bundles 221 with the same orientation.

As shown in FIG. 2J, take four fibered fabrics 220 for example, in the composite stack plate 201, the fibered fabrics 220 are respectively a glass fibered fabric 220G having 3K fibers, a unidirectional Kevlar fibered fabric 220K having 45° orientation, a unidirectional Kevlar fibered fabric 220K having 135° and a glass fibered fabric 220G having 3K fibers; and the thickness of the composite stack plate 201 is e.g., 0.6 mm˜0.8 mm.

As shown in FIG. 2K, take four fibered fabrics 220 for example, in the composite stack plate 201, the fibered fabrics 220 are respectively a Kevlar fibered fabric 220K having 3K fibers, a unidirectional glass fibered fabric 220G having 45° orientation, a unidirectional glass fibered fabric 220G having 135° and a Kevlar fibered fabric 220K having 3K fibers; and the thickness of the composite stack plate 201 is e.g., 0.6 mm˜0.8 mm.

As shown in FIG. 2L, take the five fibered fabrics 220 shown in FIG. 1B for example, in the composite stack plate 201, the fibered fabrics 220 are respectively a Kevlar fibered fabric 220K having 3K fibers, a unidirectional glass fibered fabric 220G having 0° orientation, a unidirectional glass fibered fabric 220G having 90° orientation, a unidirectional glass fibered fabric 220G having 0° orientation and a Kevlar fibered fabric 220K having 3K fibers; and the thickness of the composite stack plate 201 is e.g., 0.6 mm˜1.2 mm. The fibered fabric 220M arranged in the median layer is the unidirectional glass fibered fabric 220G having 90° orientation, the Kevlar fibered fabrics 220K having 3K fibers at the outmost layers defined at two opposite sides thereof and the unidirectional glass fibered fabrics 220G having 0° orientation next to the outmost layers not only have the same type of fibered fabrics, also have the fiber bundles 221 with the same orientation.

As shown in FIG. 2M, take three fibered fabrics 220 for example, in the composite stack plate 201, the fibered fabrics 220 are respectively a Kevlar fibered fabric 220K having 3K fibers, a glass fibered weaving canvas 220G and a Kevlar fibered fabric 220K having 3K fibers; and the thickness of the composite stack plate 201 is e.g., 0.6 mm˜0.8 mm.

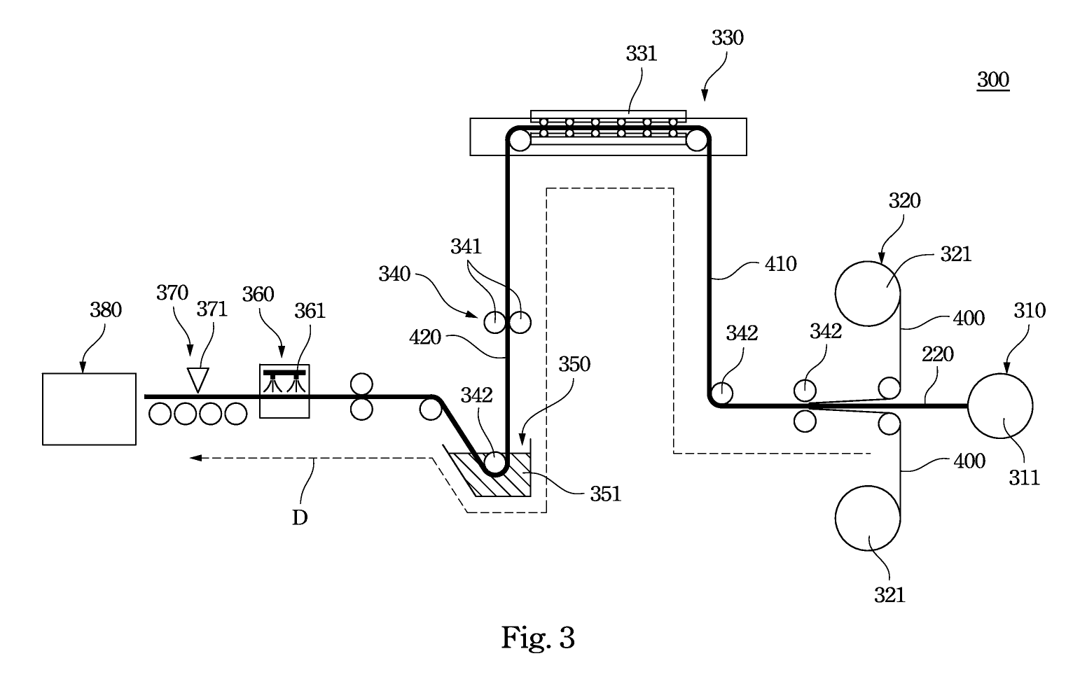

FIG. 3 is a schematic view showing equipment 300 adopted in the manufacturing method of the housing of the electronic device 100 according to one embodiment of the present disclosure.

The equipment 300 includes a fibered fabric conveying device 310, two film conveying devices 320, a heating device 330 (e.g., an oven 331), a laminating device 340 (e.g., two laminating rollers 341), a solidifying device 350 (e.g., a cooling base 351 or cool air blower), an electrostatic eliminating device 360 (e.g., a hot air blower 361), a tailoring device 370 (e.g., a tailoring knife 371), a collecting device 380 (e.g., a container). The fibered fabric conveying device 310 includes a first roller 311 defining an output end. The first roller 311 can be loaded with a reeled fibered fabric 220, and the fibered fabric 220 is not yet immersed in a liquid resin. Each film conveying device 320 includes a second roller 321 defining an input end. The second roller 321 can be loaded with a reeled resin film 400. The resin film 400 is thermoplastic, i.e., being in the solid state in room temperature and being in the liquid or paste state after being heated to a proper temperature. Thus, the manufacturing method of the housing of the electronic device 100 adopting the equipment 300 includes the following steps.

Firstly, a fibered fabric 220 and two resin films 400 are provided; the fibered fabric 220 is not limited to the types disclosed above. Substantially, the fibered fabric 220 is driven by convey rollers 342 for being conveyed towards a direction D, and continuously outputted through the first roller 311; the two resin films 400 are driven by the convey rollers 342 for being conveyed towards the direction D, and respectively outputted through the two second rollers 321.

Then, the two resin films 400 are respectively laminated at two opposite sides of the fibered fabric 220, so the fibered fabric 220 is stacked between the two resin films 400 thereby forming a laminating structure 410. Substantially, the two resin films 400 are driven by the convey rollers 342 so that the resin films 400 is directly adhered on the two opposite sides of the fibered fabric 220, and the two resin films 400 and the fibered fabric 220 jointly form the laminating structure 410 in a continuous belt shape.

Subsequently, the laminating structure 410 is heated to soften the resin films 400 at the two opposite sides of the fibered fabric 220. Substantially, the laminating structure 410 is continuously driven to pass the mentioned heating device 330, e.g., the oven 331. Through being baked in the oven 331, the resin films 440 at the two opposite sides of the fibered fabric 220 are therefore softened.

Then, the two softened resin films 440 are respectively pressed. Substantially, the laminating device 340 (e.g., the two laminating rollers 341) respectively roll and press the two softened resin films 400 at the two opposite sides of the fibered fabric 220, so the two softened resin films 440 penetrate and fill into the gaps between the fiber bundles 221 of the fibered fabric 220 (as shown in FIG. 2) so as to form a fibered fabric layer 420 integrally formed in a belt shape. When the disclosed laminating device 340 (e.g., the two laminating rollers 341) presses the laminating structure 410, the fibered fabric layer 420 can still be continuously driven for being conveyed.

Subsequently, the fibered fabric layer 420 is solidified. Substantially, the fibered fabric layer 420 is driven by the convey rollers 342 for being immersed in the solidifying device 350, e.g., the cooling case 351. The cooling case 351 enables the temperature of the resin 401 in the mentioned fibered fabric layer 420 to be cooled to room temperature, so that the fibered fabric 220 is embedded in the solidified resin 401.

Then, the cooled fibered fabric layer 420 is driven by the convey rollers 342 for being removed from the cooling case 351 and conveyed to the electrostatic eliminating device 360.

Subsequently, the fibered fabric layer 420 is tailored. Substantially, the dried fibered fabric layer 420 is driven by the convey rollers 342 for being conveyed to the tailoring device 370. For example, the tailoring knife 371 is used for tailoring the continuous fibered fabric layer 420 into a non-continuous fibered fabric layer 420. The collecting device 380 is used for collecting the non-continuous fibered fabric layer 420.

It is easy to be known that the non-continuous fibered fabric layer 420 can be seen as the mentioned resin layer having single fibered fabric.

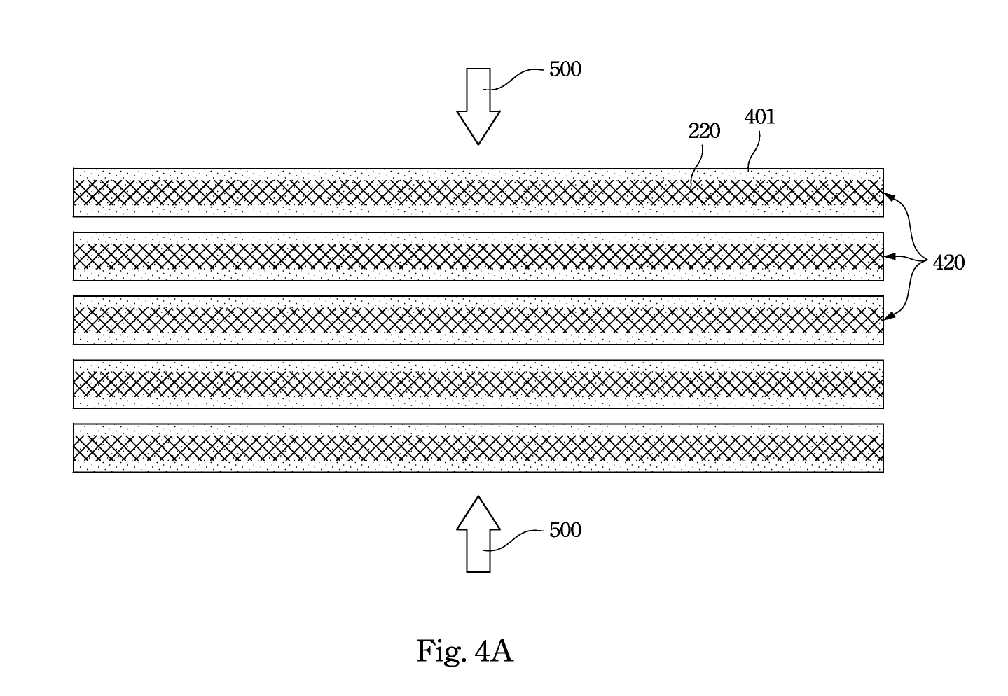

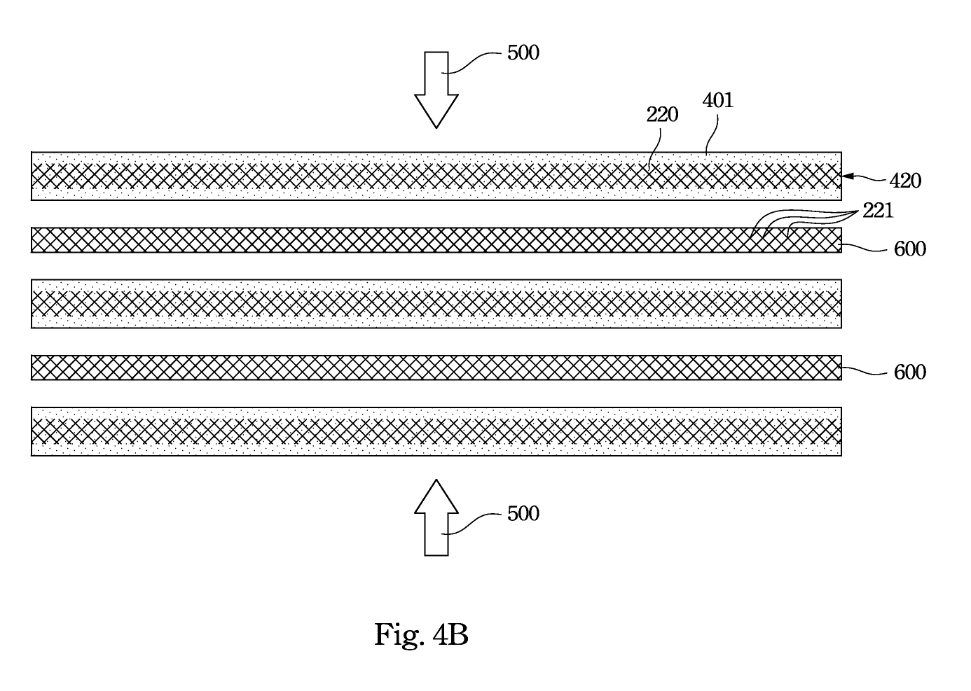

Lastly, the disclosed composite stack plate 200, 201 is formed. Substantially, FIG. 4A is a schematic view showing the operation of the manufacturing method of the housing of the electronic device 100 according to one alternative of this embodiment.

Plural of the tailored fibered fabric layers 420 are stacked with each other, and a thermal pressing tool 500 is used for thermal pressing the fibered fabric layers 420, so all the resin 401 is integrally consolidated thereby forming the disclosed composite stack plate 200, 201.

Alternatively, FIG. 4B is a schematic view showing the operation of the manufacturing method of the housing of the electronic device 100 according to another alternative of this embodiment. At least a fibered fabric 600 which is not subject to the mentioned steps is mutually stacked with one or plural of the fibered fabric layers 420 with mentioned steps, and the thermal pressing tool 500 is used for the thermal pressing operation, so all the resin 401 is integrally consolidated thereby forming the disclosed composite stack plate 201.

It is noted that the thickness of the mentioned resin film 400 can be altered according to actual needs, so the minimum distance T (as shown in FIG. 1B) defined between the surface of the two outmost fibered fabrics 220U and the surface of the resin layer 210 can be precisely controlled, or even all being the same.

When the thickness of the resin film 400 is thick enough, the surface of the resin layer 210 of the manufactured composite stack plate 201 does not allow the pattern of the fibered fabric 220U at the outmost layer to be exposed; on the other hand, when the thickness of the resin film 400 is not thick enough, the surface of the resin layer of the manufactured composite stack plate allows the pattern of the fibered fabric at the outmost layer to be exposed.

Many modifications and other embodiments of the disclosures set forth herein will come to mind to one skilled in the art to which these disclosures pertain having the benefit of the teachings presented in the foregoing descriptions and the associated drawings. Therefore, it is to be understood that the disclosures are not to be limited to the specific examples of the embodiments disclosed and that modifications and other embodiments are intended to be included within the scope of the appended claims. Although specific terms are employed herein, they are used in a generic and descriptive sense only and not for purposes of limitation.

Although the present disclosure has been described with reference to the preferred embodiments thereof, it is apparent to those skilled in the art that a variety of modifications and changes may be made without departing from the scope of the present disclosure which is intended to be defined by the appended claims.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A manufacturing method of a housing of an electronic device, comprising:
providing a first fibered fabric and two resin films;
respectively laminating the two resin films on two opposite sides of the first fibered fabric for forming a laminating structure;
heating the laminating structure for softening the two resin films of the laminating structure;
respectively pressing the two softened resin films, such that the two softened resin films are filled into gaps between fiber bundles of the fibered fabric for forming a fibered fabric layer;
solidifying the fibered fabric layer; and
stacking and thermal pressing a plurality of second fibered fabric on the fibered fabric layer for forming a composite stack plate.

2. A housing of an electronic device manufactured by the manufacturing method according to claim 1, comprising:
a composite stack plate comprising:
a resin layer; and
a plurality of fibered fabrics layered with each other, arranged at intervals, and embedded in the resin layer, each of the fibered fabrics comprising a plurality of fiber bundles,
wherein, among the layered fibered fabrics, the fiber bundles of any two symmetrical layers of the fibered fabrics have the same orientation.

3. The housing of the electronic device according to claim 2, wherein the type of each of the fibered fabrics is selected from a group consisted of a carbon fibered fabric, a glass fibered fabric and a Kevlar fibered fabric, and
any two symmetrical layers of the fibered fabrics are the same type.

4. The housing of the electronic device according to claim 2, wherein the fibered fabric is a weaving canvas, a knitting fibered fabric or a satin weaving fibered fabric.

5. The housing of the electronic device according to claim 2, wherein the amount of fibers in each of the fiber bundles of each fibered fabric is 1,000, 3,000, 6,000 or 12,000 pieces.

6. The housing of the electronic device according to claim 2, wherein the fibered fabrics are unidirectional fibered fabrics having 0°, 45°, 90° or 135° orientation.

7. The housing of the electronic device according to claim 2, wherein a minimum distance defined between one of two outmost symmetrical layers of the fibered fabrics and a minimum distance defined between the other of the two outmost layers of the fibered fabrics are the same.

8. The housing of the electronic device according to claim 2, wherein the orientations of the fiber bundles of two outmost symmetrical layers of the fibered fabrics are exposed on two outer surfaces of the resin layer.

9. A housing of an electronic device, comprising:
a composite stack plate comprising:
a resin layer; and
a plurality of fibered fabrics layered with each other, arranged at intervals, and embedded in the resin layer, each of the fibered fabrics comprising a plurality of fiber bundles,
wherein, among the layered fibered fabrics, the fiber bundles of any two symmetrical layers of the fibered fabrics have the same orientation.
